(19) United States
(12) Patent Application Publication
(10) Pub. No.: US 2017/0207085 A1
(43) Pub. Date: Jul. 20, 2017

(54) HORIZONTAL SEMICONDUCTOR DEVICE

(71) Applicant: National Tsing Hua University, Hsinchu City (TW)

(72) Inventors: Chih-Fang HUANG, Hsinchu City (TW); Keh-Yung CHENG, Hsinchu City (TW); Wei-Chen YANG, Hsinchu City (TW); Ting-Fu CHANG, Hsinchu City (TW); Po-Ju CHU, Hsinchu City (TW); Jian-Lin LIN, Hsinchu City (TW); Ya-Chu LIAO, Hsinchu City (TW); Hsin-Ying TSENG, Hsinchu City (TW)

(73) Assignee: National Tsing Hua University, Hsinchu City (TW)

(21) Appl. No.: 15/188,632

(22) Filed: Jun. 21, 2016

(30) Foreign Application Priority Data
Jan. 18, 2016 (TW) 105101379

(51) Int. Cl. H01L 21/02; H01L 29/205; H01L 29/778; H01L 29/20

(52) U.S. Cl. CPC H01L 21/02499; H01L 29/2003; H01L 29/205; H01L 29/7787; H01L 21/0254

(57) ABSTRACT

A horizontal semiconductor device includes an electrically conductive substrate having a first surface, a buffer layer disposed on the first surface of the substrate, an epitaxial unit disposed on the buffer layer opposite to the substrate, a first electrode unit disposed on the epitaxial unit, and a second electrode unit. The substrate has an exposed region that is exposed from the buffer layer and the epitaxial unit. The second electrode unit includes a first conductive member disposed on the epitaxial unit and spaced apart from the first electrode unit, and a second conductive member extending from the first conductive member to the exposed region.

### CROSS-REFERENCE TO RELATED APPLICATION

This application claims priority of Taiwanese Patent Application No. 105101379, filed on Jan. 18, 2016.

### FIELD

The disclosure relates to a semiconductor device, and more particularly to a horizontal semiconductor device.

### BACKGROUND

Referring to FIG. 1, a conventional horizontal semiconductor device includes a substrate 11, an insulating buffer layer 12 that is disposed on the substrate 11, and an epitaxial unit 13 that is disposed on the buffer layer 12 opposite to the substrate 11, and that includes a first nitride-based semiconductor layer 131 and a second nitride-based semiconductor layer 132. The conventional horizontal semiconductor device further includes a first electrode 14 that is disposed on and contacts the epitaxial unit 13, a second electrode 15 that is disposed on and contacts the epitaxial unit 13 and that is spaced apart from the first electrode 14, an insulating layer 16 that is disposed on the epitaxial unit 13 and the first and second electrodes 14, 15, a first contacting electrode 17 that is disposed on the insulating layer 16, a second contacting electrode 18 that is disposed on the insulating layer 16 and that is spaced apart from the first contacting electrode 17, a first via 101 that extends from the first contacting electrode 17 through the insulating layer 16 to contact the first electrode 14, and a second via 102 that extends from the second contacting electrode 18 through the insulating layer 16 to contact the second electrode 15.

Each of the first and second contacting electrodes 17, 18 has a contacting surface 171, 181. Each of the first and second electrodes 14, 15 has a surface 141, 151 opposite to the epitaxial unit 13. The area of the contacting surface 171, 181 of each of the first and second contacting electrodes 17, 18 is greater than that of the surface 141, 151 of each of the first and second electrodes 14, 15 for facilitating electrical connection between the conventional horizontal semiconductor device and an external device.

However, the extent to which the conventional horizontal semiconductor device can be miniaturized is limited by the size and the position of the first and second contacting electrodes 17, 18. Moreover, the fabrication process of the conventional horizontal semiconductor device will become relatively complicated if the conventional horizontal semiconductor device is to be miniaturized.

### SUMMARY

Therefore, an object of the disclosure is to provide a horizontal semiconductor device that can alleviate at least one of the drawbacks of the prior art.

The horizontal semiconductor device includes an electrically conductive substrate, a buffer layer, an epitaxial unit, a first electrode unit, and a second electrode unit.

The electrically conductive substrate has a first surface.

The buffer layer is disposed on the first surface of the substrate.

The epitaxial unit is disposed on the buffer layer opposite to the substrate, such that the first surface has an exposed region that is exposed from the buffer layer and the epitaxial unit.

The first electrode unit is disposed on the epitaxial unit.

The second electrode unit includes a first conductive member that is disposed on the epitaxial unit and that is spaced apart from the first electrode unit, and a second conductive member that extends from the first conductive member to the exposed region of the first surface.

### BRIEF DESCRIPTION OF THE DRAWINGS

Other features and advantages of the disclosure will become apparent in the following detailed description of the embodiments with reference to the accompanying drawings, of which:

FIG. 1 is a schematic view illustrating a conventional horizontal semiconductor device;

FIG. 2 is a schematic view illustrating a first embodiment of a horizontal semiconductor device according to the disclosure;

FIG. 3 is a schematic view illustrating a second embodiment of the horizontal semiconductor device according to the disclosure;

FIG. 4 is schematic view illustrating a variation of the second embodiment;

FIG. 5 is a schematic view illustrating a third embodiment of the horizontal semiconductor device according to the disclosure;

FIG. 6 is a schematic view illustrating an insulating layer and a contacting electrode formed on the first embodiment;

FIG. 7 is a plot of current density vs. forward bias voltage in a linear scale for the first embodiment;

FIG. 8 is a plot of leakage current density vs. forward bias voltage in a log scale for the first embodiment; and

FIG. 9 is a plot of current density vs. reverse bias voltage for the first embodiment.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

Referring to FIG. 2, the first embodiment of the horizontal semiconductor device according to the disclosure includes an electrically conductive substrate 21, a buffer layer 22, an epitaxial unit 23, a first electrode unit 24, a second electrode unit 25, and a passivation layer 26.

The substrate 21 has a first surface 211, and a second surface 212 that is opposite to the first surface 211. The buffer layer 22 is disposed on the first surface 211 of the substrate 21. The epitaxial unit 23 is disposed on the buffer layer 22 opposite to the substrate 21, such that the first surface 211 of the substrate 21 has an exposed region 2111 that is exposed from the buffer layer 22 and the epitaxial unit 23. The epitaxial unit 23 includes a first semiconductor layer 231 that is made of a first GaN-based material and that is disposed on the buffer layer 22, and a second semiconductor layer 232 that is made of a second GaN-based material different from the first GaN-based material and that is disposed on the first semiconductor layer 231. The first electrode unit 24 is disposed on the epitaxial unit 23. The second electrode unit 25 includes a first conductive member 251 that is disposed on the epitaxial unit 23 and that is spaced apart from the first electrode unit 24, a second conductive member 252 that extends from the first conductive member 251 to the exposed region 2111 of the first surface 211, and a third conductive member 253 that is disposed on the second surface 212 of the substrate 21, such that the third conductive member 253 is electrically connected to the second conductive member 252 of the second electrode unit 25 through the substrate 21. The passivation layer 26 is disposed on the epitaxial unit 23 and extends between the first electrode unit 24 and the first conductive member 251 of the second electrode unit 25.

In one embodiment, a junction between the first electrode unit 24 and the epitaxial unit 23 is, but not limited to, a Schottky barrier. A junction between the first conductive member 251 and the second conductive member 252 is, but not limited to, an ohmic contact.

In this embodiment, the first conductive member 251 of the second electrode unit 25 extends downwardly from the epitaxial unit 23 to the exposed region 2111 of the substrate 21, and the third conductive member 253 of the second electrode unit 25 contacts the second surface 212 of the substrate 21 and is electrically connected to an external electrical circuit. Moreover, the third conductive member 253 is disposed on the second surface 212 of the substrate 21 (i.e., backside of the substrate 21), thereby reducing a horizontal size of the first embodiment.

In one embodiment, the substrate 21 is made of a heavily doped n-type semiconductor material or a heavily doped p-type semiconductor material. That is, the substrate 21 is an n-type semiconductor substrate, or a p-type semiconductor substrate. In certain embodiments, the substrate 21 is an n-type Si substrate, or a p-type Si substrate. In certain embodiments, the substrate 21 is made of metal. In one embodiment, the buffer layer 22 and the passivation layer 26 are both electrically insulating. In certain embodiments, the buffer layer 22 includes a composite structure including GaN and AlGaN that are doped with carbon element or iron element, and the passivation layer 26 is made of SiO₂. In one embodiment, the first GaN-based material is GaN, and the second GaN-based material is AlGaN. It should be noted that properties of horizontal semiconductor devices including GaN-based materials are well known to those skilled in the art, and further details thereof are not provided hereinafter for the sake of brevity.

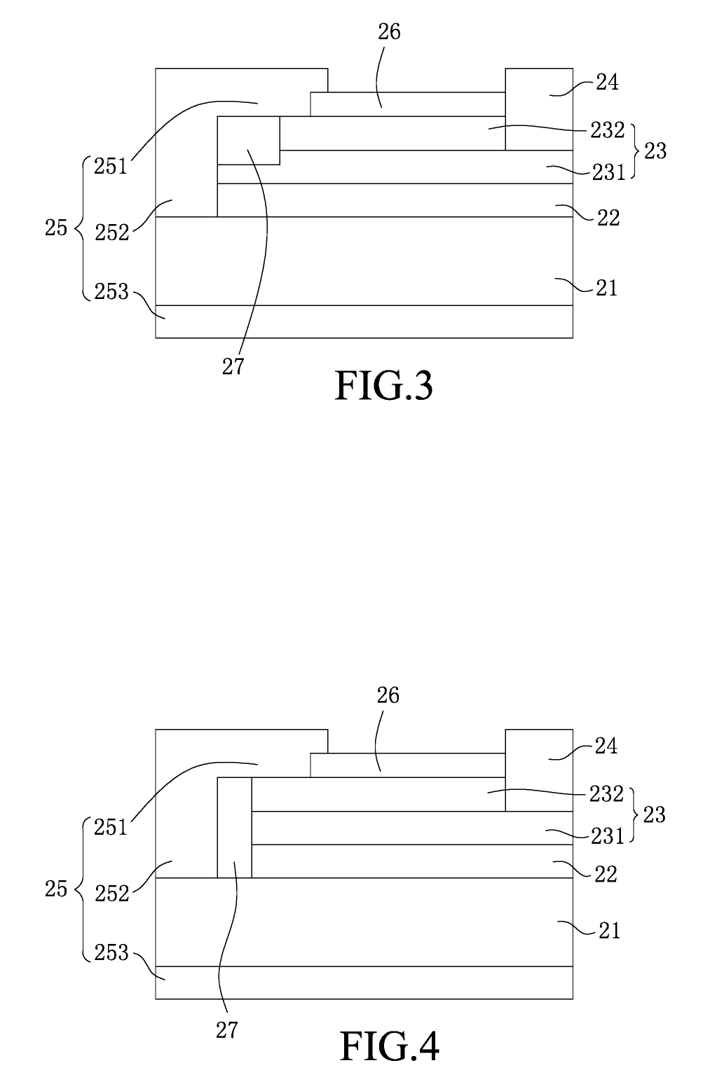

Referring to FIG. 3, a second embodiment of the horizontal semiconductor device according to this disclosure is similar to the first embodiment except that the second embodiment further includes an insulating layer 27 that is disposed between the epitaxial unit 23 and the second conductive member 252 of the second electrode unit 25. The junction between the first electrode unit 24 and the epitaxial unit 23 is, but not limited to, the ohmic contact. The junction between the first conductive member 251 and the epitaxial unit 23 is, but not limited to, the Schottky barrier. The electrical junction between the first electrode unit 24 and the epitaxial unit 23, and the electrical junction between the first conductive member 251 and the second conductive member 252 may be exchanged. More specifically, in the process of fabricating the second embodiment, the buffer layer 22 and the epitaxial unit 23 are sequentially formed on the substrate 21, followed by forming the insulating layer 27 on a side of the epitaxial unit 23, and then forming the first and second conductive members 251, 252. Thus, an undesired leakage current from the epitaxial unit 23 to the first and second conductive members 251, 252 can be restricted, and the reliability of the horizontal semiconductor device can be improved.

FIG. 4 illustrates a variation of the second embodiment, in which the epitaxial unit 23 and the second conductive member 252 of the second electrode unit 25 are separated from each other by the insulating layer 27, so that the undesired leakage current from the epitaxial unit 23 and the buffer layer 22 to the first and second conductive members 251, 252 can be minimized.

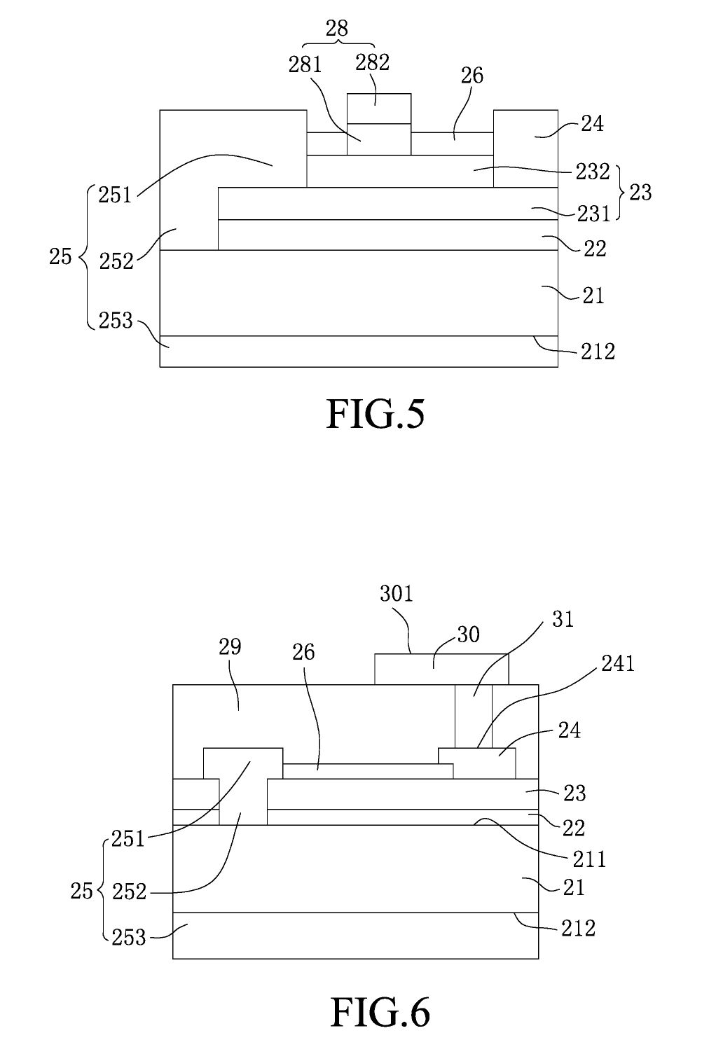

Referring to FIG. 5, a third embodiment of the horizontal semiconductor device according to this disclosure is similar to the first embodiment except that the third embodiment further includes a third electrode unit 28 that is disposed between the first electrode unit 24 and the first conductive member 251 of the second electrode unit 25 and that extends through the passivation layer 26 to contact the epitaxial unit 23. More specifically, the third embodiment may serve as a high-electron-mobility transistor (HEMT), in which the first and second electrode units 24, 25 respectively serve as a drain electrode unit and a source electrode unit, and the third electrode unit 28 serves as a gate electrode unit. When the first electrode unit 24 is a source electrode unit, the third conductive member 253 disposed on the second surface 212 of the substrate 21 is a drain electrode and is electrically connected to the external circuit. When the first electrode unit 24 is the drain electrode unit, the third conductive member 253 disposed on the second surface 212 of the substrate 21 is the source electrode. In one embodiment, the third electrode unit 28 includes a third semiconductor layer 281 that is formed on the second semiconductor layer 232 and that is made of a third GaN-based material different from the second GaN-based material, and a metal layer 282 that is formed on the third semiconductor layer 281. The third electrode unit 28 is not limited to the above-mentioned structure. In one embodiment, the third GaN-based material is p-type GaN. In certain embodiments, the third electrode 28 may be an MIS gate, a Schottky gate, or a P-GaN gate.

FIG. 6 illustrates a variation of the first embodiment, in which the second conductive member 252 of the second electrode unit 25 extends from the first conductive member 251, penetrates through the epitaxial unit 23 and the buffer layer 22, and contacts the exposed region 2111 of the substrate 21. That is, a gap is formed to extend through the epitaxial unit 23 and the buffer layer 22 by, e.g., deep etching techniques, and the second conductive member 252 is then formed in the gap to contact the exposed region 2111 of the substrate 21. For further application, an insulator 29, a via 31, and a contacting electrode 30 may be further formed.

To be more specific, the insulator 29 covers the epitaxial unit 23, the first electrode unit 24 and the first conductive member 251 of the second electrode unit 25 so as to protect the horizontal semiconductor device from external pollution. The contacting electrode 30 is formed on the insulator 29. The via 31 extends from the first electrode unit 24, passes through the insulator 29, and contacts the contacting electrode 30.

The contacting electrode 30 has a contacting surface 301 opposite to the insulator 29. The first electrode unit 24 has a surface 241 opposite to the epitaxial unit 23. The area of the contacting surface 301 of the contacting electrode 30 is greater than that of the surface 241 of the first electrode unit 24, such that the first electrode unit 24 can be electrically connected to the external circuit through the contacting electrode 30 in an efficient way. In addition, the third conductive member 253 of the second electrode unit 25 is designed to contact the external circuit.

Since the contacting electrode 30 and the third conductive member 253 are respectively disposed on the opposite first and second surfaces 211, 212 of the substrate 21, the horizontal dimension of the horizontal semiconductor device may be reduced. As a result, the first conductive member 251 of the second electrode unit 25 can be completely covered by the insulator 29 without the need for formation of an additional contact electrode that penetrates the insulator 29 to contact the external circuit, thereby reducing manufacturing costs.

<Performance Test>

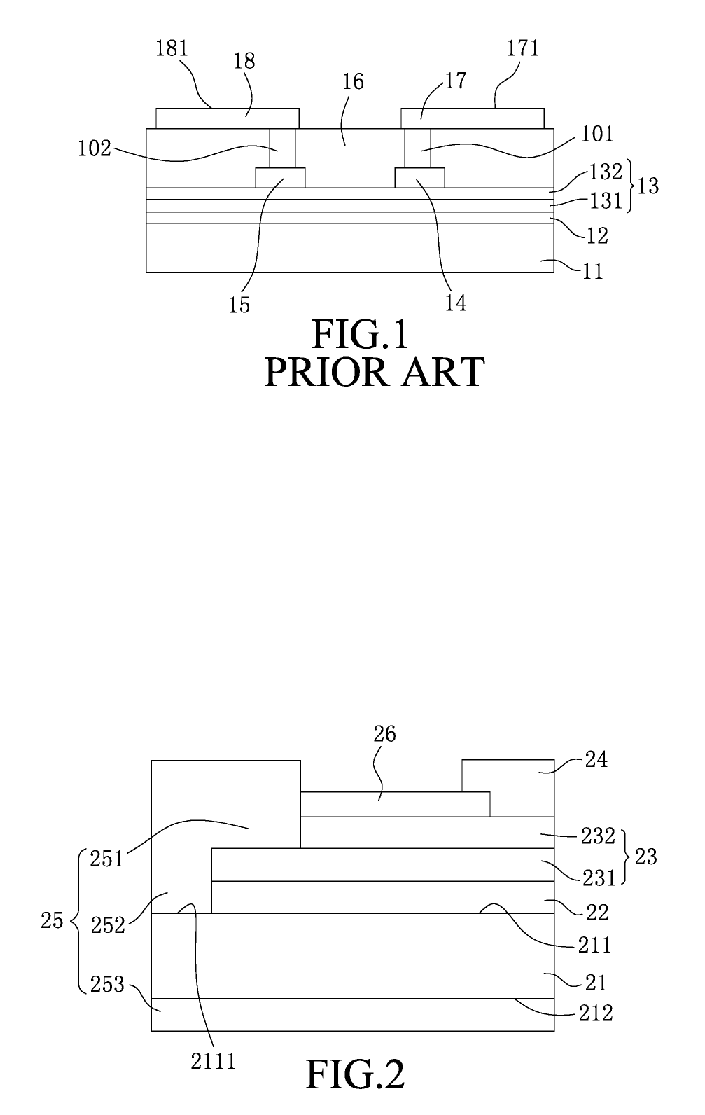

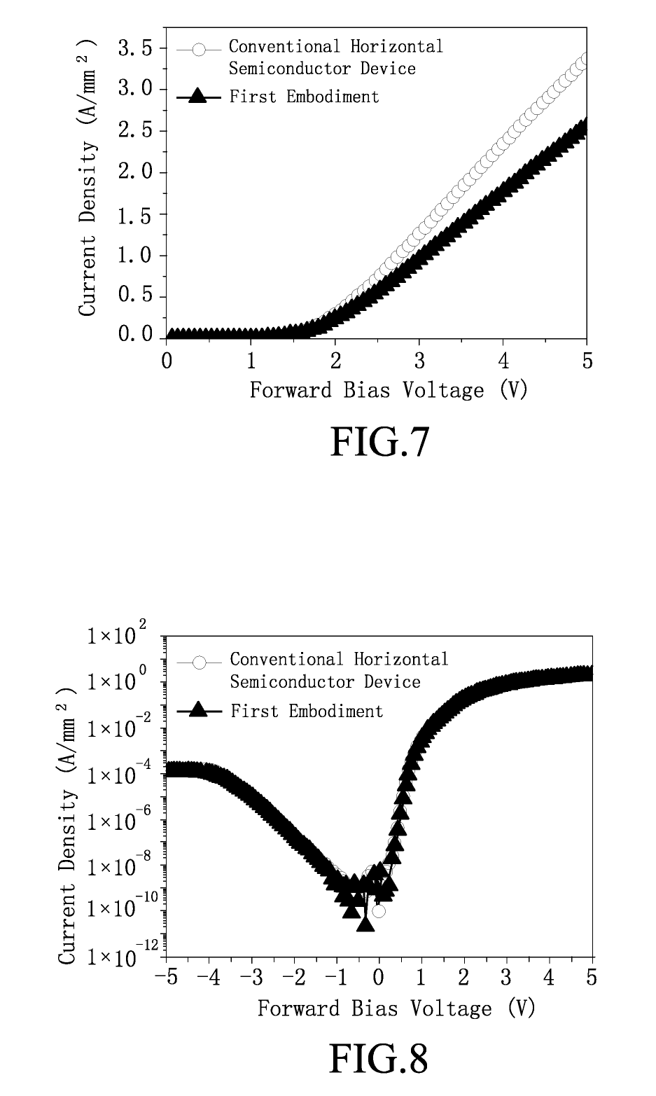

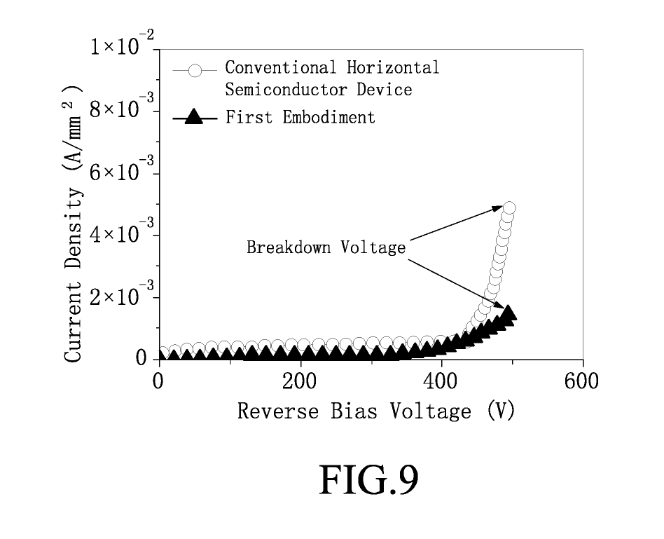

Sample devices of the aforesaid conventional horizontal semiconductor device of FIG. 1, and the first embodiment of the horizontal semiconductor device shown in FIG. 2 were prepared for a conductivity test, a leakage current test, and a breakdown voltage test. The first and second contacting electrodes 17, 18 of the conventional horizontal semiconductor device contact an external electric measurement device. The first electrode unit 24 and the third conductive member 253 of the second electrode unit 25 of the first embodiment contact the external measurement device. FIG. 7 is a plot of current density (A/mm²) vs. forward bias voltage (V) to determine the conductivity. FIG. 8 is a plot of current density (A/mm²) vs. forward bias voltage (V) in a log scale to determine the leakage current. FIG. 9 is a plot of current density (A/mm²) vs. reverse bias voltage (V) in a linear scale to determine the breakdown voltage. The results indicate that the conductivity, the leakage current, and the breakdown voltage of the first embodiment are relatively stable and similar to those of the conventional horizontal semiconductor device.

In summary, in this disclosure, the third conductive member 253 of the second electrode unit 25 and the first electrode unit 24 are respectively disposed on opposite sides of the substrate 21 to contact the external circuit, thereby reducing the horizontal dimension of the horizontal semiconductor device and simplifying the fabrication process of the horizontal semiconductor device. The horizontal semiconductor device of this disclosure has similar performance compared to that of the conventional horizontal semiconductor device and meets industrial requirements.

In the description above, for the purposes of explanation, numerous specific details have been set forth in order to provide a thorough understanding of the embodiments. It will be apparent, however, to one skilled in the art, that one or more other embodiments may be practiced without some of these specific details.

It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding various inventive aspects.

While the disclosure has been described in connection with what is considered the exemplary embodiments, it is understood that this disclosure is not limited to the disclosed embodiment but is intended to cover various arrangements included within the spirit and scope of the broadest interpretation so as to encompass all such modifications and equivalent arrangements.

What is claimed is:

1. A horizontal semiconductor device comprising:
an electrically conductive substrate having a first surface;
a buffer layer disposed on said first surface of said substrate;
an epitaxial unit disposed on said buffer layer opposite to said substrate, such that said first surface has an exposed region that is exposed from said buffer layer and said epitaxial unit;
a first electrode unit disposed on said epitaxial unit; and
a second electrode unit including a first conductive member that is disposed on said epitaxial unit and that is spaced apart from said first electrode unit, and a second conductive member that extends from said first conductive member to said exposed region of said first surface.

2. The horizontal semiconductor device of claim 1, wherein said substrate further has a second surface that is opposite to said first surface, said second electrode unit further including a third conductive member that is disposed on said second surface of said substrate such that said third conductive member is electrically connected to said second conductive member of said second electrode unit through said substrate.

3. The horizontal semiconductor device of claim 1, further comprising a third electrode unit and a passivation layer, said passivation layer being disposed on said epitaxial unit and extending between said first electrode unit and said first conductive member of said second electrode unit, said third electrode unit being disposed between said first electrode unit and said first conductive member of said second electrode unit and extending through said passivation layer to contact said epitaxial unit.

4. The horizontal semiconductor device of claim 1, wherein said substrate is an n-type semiconductor substrate.

5. The horizontal semiconductor device of claim 1, wherein said substrate is a p-type semiconductor substrate.

6. The horizontal semiconductor device of claim 1, wherein said substrate is made of metal.

7. The horizontal semiconductor device of claim 1, further comprising an insulating layer that is disposed between said epitaxial unit and said second conductive member of said second electrode unit.

8. The horizontal semiconductor device of claim 7, wherein said epitaxial unit and said second conductive member of said second electrode unit are separated from each other by said insulating layer.

9. The horizontal semiconductor device of claim 1, wherein said second conductive member of said second electrode unit extends from said first conductive member, penetrates through said epitaxial unit and said buffer layer, and contacts said exposed region of said substrate.

10. The horizontal semiconductor device of claim 1, wherein said epitaxial unit includes a first semiconductor layer that is made from a first GaN-based material and that is disposed on said buffer layer, and a second semiconductor layer that is made from a second GaN-based material different from said first GaN-based material and that is disposed on said first semiconductor layer.

11. The horizontal semiconductor device of claim 10, wherein said first GaN-based material is GaN, and said second GaN-based material is AlGaN.
